(19) United States
(12) Patent Application Publication
(10) Pub. No.: US 2026/0128734 A1
(43) Pub. Date: May 7, 2026

(54) PULSE OUTPUT DEVICE, LASER SYSTEM AND METHOD FOR OUTPUTTING PULSES

(71) Applicant: TRUMPF Laser SE, Schramberg (DE)

(72) Inventors: Michael Harteker, Rottweil (DE); Rainer Flaig, Eschbronn (DE); Oliver Rapp, Schramberg (DE); Thomas Haas, Hardt (DE)

(21) Appl. No.: 19/439,512

(22) Filed: Jan. 5, 2026

Related U.S. Application Data
(63) Continuation of application No. PCT/EP2024/069631, filed on Jul. 11, 2024.

(30) Foreign Application Priority Data
Jul. 11, 2023 (DE) 10 2023 118 275.7

(51) Int. Cl. H03K 5/05; H01S 3/102; H03K 5/131; H03K 5/135

(52) U.S. Cl. CPC H03K 5/05; H01S 3/1024; H03K 5/131; H03K 5/135

(57) ABSTRACT

A pulse output device includes a digital pulse generator for outputting at least one output pulse triggered by a trigger signal. The digital pulse generator has a trigger input for the trigger signal and a clock input for a clock signal. The pulse output device further includes a clock generator for generating the clock signal, and a clock splitter. For synchronization of the clock signal with the trigger signal, the pulse output device is configured to stop the clock splitter, which is configured to reduce a clock rate of the clock signal, and/or to stop the clock generator before the clock signal is fed to the clock input of the digital pulse generator, and to restart the clock splitter and/or the clock generator synchronously with the trigger signal.

### CROSS REFERENCE TO RELATED APPLICATIONS

This application is a continuation of International Application No. PCT/EP2024/069631 (WO 2025/012370 A1), filed on Jul. 11, 2024, and claims benefit to German Patent Application No. DE 10 2023 118 275.7, filed on Jul. 11, 2023. The aforementioned applications are hereby incorporated by reference herein.

### FIELD

Embodiments of the present invention relate to a pulse output device. Embodiments of the present invention also relate to a laser system which has such a pulse output device, and to a method for outputting by a digital pulse generator at least one pulse triggered by a trigger signal.

### BACKGROUND

The digital pulse generator is used for discrete sampling or discrete reading of the (external) trigger signal. When the external event (trigger), which is non-synchronous with the clock, is read by the digital pulse generator, a temporal discretization of the event occurs, as in all digital clock-based systems, which leads to a jitter (clock jitter) relative to the external trigger signal. The jitter is primarily determined by the chosen base clock of the clock signal or the sampling rate of the discrete or digital clock-based system. For many applications, the occurrence of jitter is undesirable, as synchronization with other systems or components is no longer possible in an ideal manner.

The digital pulse generator or pulse output device can, for example, be used to control a laser source of an (ultrashort pulse) laser system in order to use the laser system in “pulse-on-demand” operation, i.e., to generate laser pulses with freely selectable triggering. A digital pulse generator of a laser control system of such a laser system typically operates with clock signals which have clock rates in the order of approximately 50 MHz to approximately 100 MHz or possibly up to 200 MHz. When clock rates of the order of magnitude described here are used to sample an external, random trigger signal (e.g., for a laser pulse request), a discrete jitter in the order of +/−5 ns is typically generated. A reduction in jitter could be achieved by increasing the sampling rate or clock rate of the digital pulse generator, but this would result in an increase in the costs of the electronic components. Furthermore, increasing the clock rate of the digital pulse generator is technically limited.

To synchronize circuit components, phase-locked loops are typically used, which typically do not require a trigger event, but rather a recurring clock signal to which another clock signal can synchronize. Furthermore, this process requires several clock edges of the external signal, which necessitates a duration in the order of approximately 10 to 100 μs.

CN112968690A describes a high-precision pulse generator with low jitter. The pulse generator features a time-to-digital converter module in the form of an FPGA, which determines the time interval between the external trigger signal and the clock signal in order to compensate for the jitter output of the pulse. A jitter compensation module processes the time information measured by the time-to-digital converter module and the delay time specified by an operator to obtain the final delay information for pulse compensation. The delay should achieve a precision of 22 ps, and the jitter of the output pulse should be 500 ps.

TW201249107A describes a mechanism for generating an event-triggered pulse wave, which comprises a microcontroller. The width of the output pulse wave can be adjusted to the clock width of a clock signal using an algorithm, and the rising edge of the system can be synchronized. The microcontroller has two interrupt terminals for this purpose.

### SUMMARY

Embodiments of the present invention provide a pulse output device. The pulse output device includes a digital pulse generator for outputting at least one output pulse triggered by a trigger signal. The digital pulse generator has a trigger input for the trigger signal and a clock input for a clock signal. The pulse output device further includes a clock generator for generating the clock signal, and a clock splitter. For synchronization of the clock signal with the trigger signal, the pulse output device is configured to stop the clock splitter, which is configured to reduce a clock rate of the clock signal, and/or to stop the clock generator before the clock signal is fed to the clock input of the digital pulse generator, and to restart the clock splitter and/or the clock generator synchronously with the trigger signal.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic representation of a block diagram of a laser system for generating laser pulses, which has a pulse output device and a laser source, according to some embodiments;

FIG. 2 shows schematic representations of temporal signal waveforms at different positions of the laser system of FIG. 1 without synchronization of a clock signal of a digital pulse generator with a trigger signal taking place;

FIG. 3 shows a schematic representation analogous to FIG. 2 with synchronization of the clock signal with the trigger signal taking place by stopping and restarting a clock splitter according to some embodiments; and

FIG. 4 shows a schematic representation analogous to FIG. 2 with an additional temporal synchronization of the clock signal with the trigger signal taking place by stopping and restarting a clock generator according to some embodiments.

### DETAILED DESCRIPTION

Embodiments of the present invention provide a pulse output device, a laser system having such a pulse output device, and a method for outputting pulses with very low jitter with respect to an external trigger signal.

According to a first aspect, a pulse output device, for synchronization of the clock signal with the trigger signal, is configured to stop a clock splitter of the pulse output device, which is configured to reduce a clock rate of the clock signal, and/or to stop the clock generator before the clock signal is fed to the clock input of the digital pulse generator and to restart the clock splitter and/or the clock generator synchronously with the trigger signal.

In the pulse output device described here, the clock generator or a clock splitter designed to reduce the clock signal generated by the clock generator is stopped or reset and restarted time-synchronously with the trigger signal. The external event in the form of the trigger signal, which can be in the form of a single edge or a single trigger pulse, is not directly read or sampled by the digital pulse generator in this case, but is used to asynchronously reset or stop the clock generator or clock splitter and restart it in a defined manner in response to the external event. In this way, the sampling rate of the digital pulse generator can be synchronized to the external event. The event itself or the trigger signal, e.g., in the form of a trigger pulse, is then read by the synchronized digital pulse generator. In this way, jitter can be significantly reduced.

In principle, there are two possibilities or approaches for synchronizing the clock signal with the trigger signal, which can also be combined with one another:

In the first option, the pulse output device has a clock splitter which is designed to be reset or stopped by the trigger signal and restarted time-synchronously with the trigger signal. In this case, the clock generator is typically designed to generate a clock signal with a significantly higher clock rate than the clock rate that the digital pulse generator can process. The clock splitter is used to reduce the clock rate to a predetermined (integer) fraction of the clock rate of the clock generator, which corresponds to the sampling rate of the digital pulse generator. With this option, by synchronizing the clock signal with the trigger signal, jitter can be significantly reduced to a jitter that corresponds to the higher clock rate of the clock generator, without having to operate the digital pulse generator at the higher clock rate of the clock generator for this purpose. For example, with a clock rate of 800 MHz, a jitter of +/−1/800 MHz=+/-1.25 ns can be generated, which corresponds to an improvement by a factor of 16 relative to the jitter generated with a clock rate of the digital pulse generator of, for example, 50 MHz.

With the second option, the clock generator is designed to be reset or stopped by the trigger signal and then restarted synchronously with the external trigger or trigger signal (freewheel oscillator). The second option does not necessarily require a clock splitter, but this can still be used, in particular for combining both options. With the second option or solution approach, the jitter can be reduced to less than 500 ps. By combining both approaches it is possible to reduce the jitter to less than 300 ps.

With both options, the digital pulse generator can be synchronized to the external trigger signal within a few tens to hundreds of nanoseconds.

In one embodiment, the pulse output device has a feed device for feeding the trigger signal to the clock generator and/or to the clock splitter. The feed device (e.g., in the form of a trigger/stop logic) feeds the trigger signal to the clock generator and/or the clock splitter. The feed device is typically also designed to additionally direct the trigger signal towards the trigger input of the digital pulse generator.

In a further embodiment, the clock splitter and/or the clock generator is/are designed to stop on a first edge of the fed trigger signal and to restart on a second edge of the fed trigger signal. In this case, the trigger signal is typically in the form of a trigger pulse, which has a first, rising edge and a second, falling edge, or vice versa. It is fundamentally possible that the external trigger signal consists of only a single rising or falling edge and that a trigger pulse is generated from the external trigger signal or the trigger edge by means of the feed device, e.g., in the form of the trigger/stop logic.

In a further embodiment, the pulse output device comprises a delay device for delaying the trigger signal before it is fed to the trigger input of the digital pulse generator. In this embodiment, the trigger signal is time-delayed before it is fed to the trigger input. The time delay provides a sufficient time period in which to synchronize further components with the clock signal that has been synchronized with the trigger signal.

In a further embodiment, the pulse output device has a clock distributor for distributing the clock signal synchronized with the trigger signal. The clock distributor serves to transmit the clock signal to other digital components or circuit parts besides the digital pulse generator in order to appropriately synchronize them with the pulse generated by the digital pulse generator.

In one embodiment, the digital pulse generator is designed to delay the output pulse by a predetermined number of clock cycles of the clock signal. The digital pulse generator can, in principle, output one or at least one pulse as soon as the trigger signal synchronized with the clock signal or the trigger pulse is present at the trigger input. However, the digital pulse generator can also be designed to delay the synchronously read trigger by a predetermined or predefinable number of clock cycles and only output the pulse after this predefined delay. Before the pulse is output, other components can be triggered/controlled by the digital pulse generator in this case, which must be set before the pulse is triggered. In the event that the output pulse is used to generate a laser pulse, such a component could, for example, be a mechanical shutter that must be opened before the laser pulse is generated.

In a further embodiment, the clock splitter is designed to reduce the clock rate of the clock signal generated by the clock generator by at least 1:8, preferably by at least 1:16. As described above, jitter can typically be reduced at least in proportion to the reduction of the clock rate by the clock splitter. The clock rate of the clock generator can be significantly higher than the clock rate of the digital pulse generator. For example, the digital pulse generator can be operated at a clock rate of 50 MHz and the clock generator can be operated at a clock rate of 800 MHz. In this case, the clock rate is reduced by the clock splitter by the ratio 1:16.

In a further embodiment, the digital pulse generator is designed as an FPGA (field programmable gate array) or as a microcontroller. An FPGA is an integrated circuit used in digital technology, into which a logic circuit can be loaded. A microcontroller is a semiconductor chip that also performs peripheral functions in addition to that of a processor. As described above, a digital pulse generator designed in this manner cannot be operated at an arbitrarily high clock rate, which is why the use of a clock splitter to reduce the clock rate of the clock generator has proven advantageous.

A further aspect of the invention relates to a laser system. The laser system comprising: a pulse output device designed as described above, and a laser source for generating laser pulses synchronized with the pulses output by the digital pulse generator. The start time of each laser pulse typically coincides with the start time of each pulse generated by the digital pulse generator (or each laser pulse has a fixed delay).

The jitter of the laser pulses requested with the trigger signal can be reduced to less than 2 ns (3 sigma), or possibly significantly less than 2 ns, in the manner described above. Laser pulses can be requested (pulse on demand) with a trigger-to-light delay of just a few microseconds. In principle, it would also be possible to trigger the laser pulses of the laser source directly with an external trigger signal, but in this case it is not possible to start several circuit parts synchronously or with a time offset, as is the case when using the digital pulse generator for generating or triggering the (laser) pulses.

A further aspect of the invention relates to a method for outputting, by a digital pulse generator, at least one pulse triggered by a trigger signal, in which, for synchronization of the clock signal with the trigger signal, a clock generator for generating the clock signal and/or a clock splitter for reducing a clock rate of the clock signal is/are stopped before the clock signal is fed to the clock input of the digital pulse generator and the clock generator and/or the clock splitter is/are restarted synchronized with the trigger signal. The method described here has the advantages described further above in association with the pulse output device.

In the following description of the drawings, identical reference numerals are used for identical or functionally identical components.

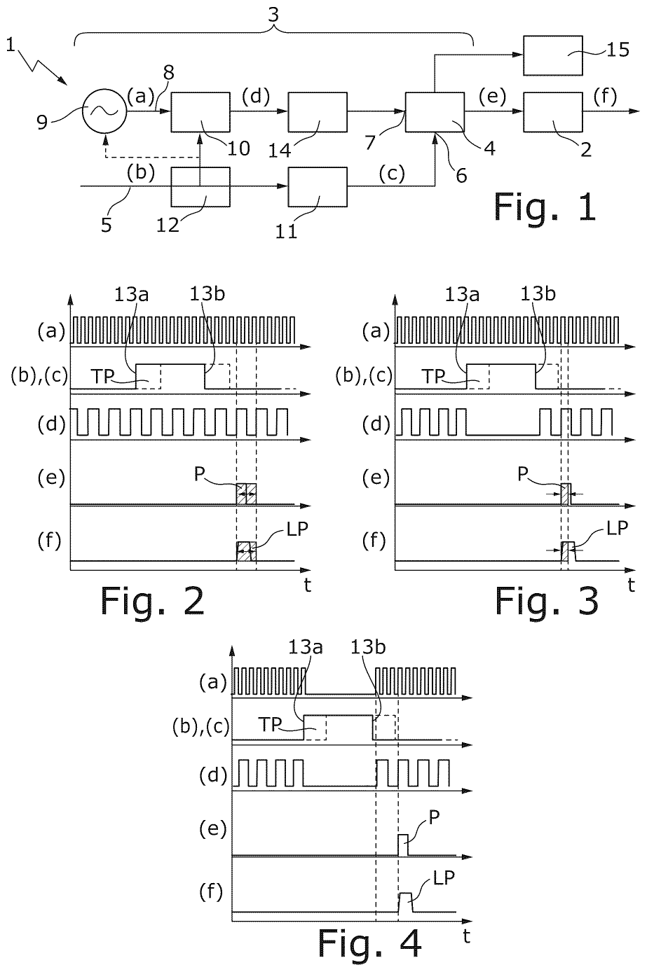

FIG. 1 shows a laser system 1 having a laser source 2 and a pulse output device 3. The pulse output device 3 has a digital pulse generator 4, which in the example shown is designed as an FPGA and is operated at a clock rate of 50 MHz. Alternatively, the pulse output device 3 can also be designed as a microcontroller or the like and operated at a different clock rate. The digital pulse generator 4 is designed to output pulses P triggered by an external trigger signal 5. Such a pulse P is shown in FIG. 2, FIG. 3 and FIG. 4, in which the temporal signal waveforms at the points labeled (a) to (f) in FIG. 1 are shown.

The laser source 2 is used to generate laser pulses LP (see (f) in FIGS. 2 to 4) which are synchronized with the pulses P output by the digital pulse generator 4, i.e., the start times of the laser pulses LP are almost identical to the start times of the pulses P. The pulse output device 3 thus serves to trigger the laser pulses LP depending on the external trigger signal 5, which is used to request a respective laser pulse LP (pulse-on-demand).

The digital pulse generator 4 has a trigger input 6 for feeding the trigger signal 5 and a clock input 7 for a clock signal 8, which is generated by a clock generator 9 of the pulse output device 3. In the example shown, the clock generator 9 is designed to generate a clock signal 8 with a clock rate of 800 MHz (see (a) in FIGS. 2 to 4). In the example shown, the pulse output device 3 has a clock splitter 10, which is designed to split or reduce the clock rate of the clock generator 9 in the ratio 1:16, in order to reduce the clock rate of the clock signal 8 to 50 MHz (see (d) in FIGS. 2 to 4), which corresponds to the clock rate of the digital pulse generator 4.

In the example shown, the trigger signal 5 is in the form of a trigger pulse TP (see (b), (c) in FIGS. 2 to 4). A delay unit 11 is used to delay the trigger signal 5 or the trigger pulse TP. In FIG. 2, the trigger pulse TP at point (c) after passing through the delay unit 11 is indicated by a dashed line.

If the clock signal 8 with a clock rate of 50 MHz, which is applied to the clock input 7, is used without further measures for sampling the trigger signal 5, a jitter in the order of approximately +/−10 ns (20 ns in total) is generated. Such a sampling process, in which no synchronization takes place between the trigger signal 5 and the clock signal 8, is shown in FIG. 2.

In order to reduce the temporal jitter which occurs when sampling the trigger signal 5 using the digital pulse generator 4, the pulse output device 3 is designed to synchronize the clock signal 8 with the trigger signal 5 before the clock signal 8 is fed to the clock input 7 of the digital pulse generator 4. For synchronization, the clock splitter 10 and/or the clock generator 9 can be designed to be stopped and restarted synchronously with the trigger signal 5. In the example shown, the pulse output device 3 has a feed device 12 which is designed to feed the trigger signal 5 to both the clock splitter 10 and the clock generator 9.

To reduce jitter, it is not absolutely necessary to stop and restart both the clock splitter 10 and the clock generator 9. Rather, it is sufficient if only the clock splitter 10 is stopped and restarted, as illustrated by the signal waveforms shown in FIG. 3. In this case, the temporal jitter can be reduced by a ratio of 1:16 of the clock splitter 10 and corresponds to the temporal jitter that would be generated if the digital pulse generator 4 were operated at the clock rate of the clock generator 9.

FIG. 4 illustrates the case where both the clock splitter 10 and the clock generator 9 are stopped and restarted. In this case, the temporal jitter can be reduced by an even greater degree than in the case described in FIG. 4. It is also possible to only stop and restart the clock generator 9, in which case the clock splitter 10 can be dispensed with.

In the cases described in FIG. 2 and FIG. 3, the clock splitter 10 or the clock generator 9 is stopped after a first, rising edge 13a of the trigger pulse TP of the trigger signal 5 and restarted after a second, falling edge 13b of the trigger pulse TP. The pulse P of the digital pulse generator 4 is triggered by the falling edge 13b of the (time-delayed) trigger pulse TP. It is understood that stopping or restarting the clock splitter 10 or the clock generator 9 depending on the trigger signal 5 can be implemented in other ways.

In the cases described in FIG. 2 and FIG. 3, the clock signal 8 is synchronized with the trigger signal 5 after passing through the clock splitter 10 and is distributed by a clock distributor 14 to further components or circuit parts not shown in the drawing, in order to synchronize them with the pulse P generated by the digital pulse generator 4 or with the laser pulse LP.

In the example shown in FIG. 1, the digital pulse generator 4 is designed to delay the output pulse P by a predetermined number of clock cycles of the clock signal 8. Before the pulse P is output, in this case 4 other components can be triggered/controlled by the digital pulse generator, which must be set before the pulse P is output. FIG. 1 shows an example of such a component 15, which is a mechanical shutter that must be opened before the laser pulse LP is generated.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A pulse output device, comprising:
a digital pulse generator for outputting at least one output pulse triggered by a trigger signal, wherein the digital pulse generator has a trigger input for the trigger signal and a clock input for a clock signal,
a clock generator for generating the clock signal, and
a clock splitter,
wherein,
for synchronization of the clock signal with the trigger signal, the pulse output device is configured to stop the clock splitter, which is configured to reduce a clock rate of the clock signal, and/or to stop the clock generator before the clock signal is fed to the clock input of the digital pulse generator, and to restart the clock splitter and/or the clock generator synchronously with the trigger signal.

2. The pulse output device according to claim 1, further comprising a feed device for feeding the trigger signal to the clock splitter and/or to the clock generator.

3. The pulse output device according to claim 2, wherein the clock splitter and/or the clock generator is/are configured to stop on a first edge of the trigger signal and to restart on a second edge of the trigger signal.

4. The pulse output device according to claim 1, further comprising a delay device for delaying the trigger signal before the trigger signal is fed to the trigger input of the digital pulse generator.

5. The pulse output device according to claim 1, further comprising a clock distributor for distributing the clock signal synchronized with the trigger signal.

6. The pulse output device according to claim 1, wherein the digital pulse generator is configured to delay the output pulse by a predetermined number of clock cycles of the clock signal.

7. The pulse output device according to claim 1, wherein the clock splitter is used to reduce the clock rate of the clock signal generated by the clock generator by at least 1:8.

8. The pulse output device according to claim 1, wherein the digital pulse generator is configured as a field-programmable gate arrays (FPGA) or as a microcontroller.

9. A laser system comprising:
a pulse output device according to claim 1, and a laser source for generating at least one laser pulse, wherein the laser pulse is synchronized with the at least one output pulse output by the digital pulse generator.

10. A method for outputting, by a digital pulse generator, at least one output pulse triggered by a trigger signal, the method comprising:
feeding the trigger signal to a trigger input of the digital pulse generator,
feeding a clock signal to a clock input of the digital pulse generator,
outputting, by the digital pulse generator, the at least one output pulse triggered by the trigger signal, and
for synchronization of the clock signal with the trigger signal, stopping a clock generator for generating the clock signal and/or a clock splitter for reducing a clock rate of the clock signal before the clock signal is fed to the clock input of the digital pulse generator, and restarting the clock generator and/or the clock splitter synchronously with the trigger signal.
